(19) United States
(12) Patent Application Publication
(10) Pub. No.: US 2014/0166064 A1
(43) Pub. Date: Jun. 19, 2014

(54) THERMOELECTRIC CONVERSION MODULE AND METHOD FOR PRODUCING THE SAME

(71) Applicant: Murata Manufacturing Co., Ltd., Nagaokakyo-shi (JP)

(72) Inventor: Takanori NAKAMURA, Nagaokakyo-shi (JP)

(73) Assignee: MURATA MANUFACTURING CO., LTD., Nagaokakyo-shi (JP)

(21) Appl. No.: 14/186,153

(22) Filed: Feb. 21, 2014

Related U.S. Application Data
(63) Continuation of application No. PCT/JP2012/070879, filed on Aug. 17, 2012.

(30) Foreign Application Priority Data
Aug. 22, 2011 (JP) 2011-180238

(51) Int. Cl. H01L 35/32; H01L 35/34

(52) U.S. Cl. CPC H01L 35/32; H01L 35/34
USPC 136/205; 438/54; 136/201

(57) ABSTRACT

In a thermoelectric conversion module having a stack structure in which one-side element (p-type thermoelectric conversion element) and an other-side element (thermoelectric conversion element) are alternately stacked; the one-side element and the other-side element are directly bonded in some regions of a bonding surface at which the one-side element and the other-side element are bonded; and the one-side element and the other-side element are bonded via insulating material in other regions of the bonding surface, at least one of the one-side element and the other-side element is a thermoelectric conversion element including a thermoelectric conversion material powder made of an intermetallic compound and a metal powder and being retained to have a predetermined shape by a cured resin.

### BACKGROUND OF THE INVENTION

1. Field of the Invention

The present invention relates to a thermoelectric conversion module and a method for producing the same.

2. Description of the Related Art

In recent years, for prevention of global warming, reduction of carbon dioxide has become a critical problem, so that a thermoelectric conversion element capable of directly converting heat into electricity is attracting people's attention as one of the effective technical measures for utilizing waste heat.

Further, as a conventional thermoelectric conversion module, there are proposed, for example, a thermoelectric conversion element having a structure such that a p-type oxide thermoelectric conversion material and an n-type oxide thermoelectric conversion material are directly bonded in some regions of a bonding surface at which the p-type oxide thermoelectric conversion material and the n-type oxide thermoelectric conversion material are bonded, and the p-type oxide thermoelectric conversion material and the n-type oxide thermoelectric conversion material are bonded via an insulating material in other regions of the bonding surface, wherein the p-type oxide thermoelectric conversion material, the n-type oxide thermoelectric conversion material, and the insulating material are simultaneously sintered, as well as a thermoelectric conversion module using the same. See, for example, International Application Publication No. 2009/001691).

According to the invention described in International Application Publication No. 2009/001691, it is possible to realize a thermoelectric conversion module having a large occupancy of the thermoelectric conversion material in which the p-type thermoelectric conversion material and the n-type thermoelectric conversion material are directly bonded.

Also, as a thermoelectric conversion element and a method for producing the same, there are proposed a FeSi₂ thermal power-generating element in which a FeSi₂ source material powder prepared to be of p-type or n-type is bonded by using, as a binder, a Cu-containing resin in which a Cu component is uniformly dispersed in the resin, followed by degreasing, sintering, and thermal treating, as well as a method for producing the same. See, for example, Japanese Patent Application Laid-open No. 08-139368.

According to the invention described in Japanese Patent Application Laid-open No. 08-139368, it is supposed that the thermal treatment time can be greatly reduced, and a FeSi₂ thermal power-generating element having a high productivity can be provided.

Also, as another thermoelectric conversion module, there is proposed a method for producing a thermoelectric conversion module in which each of the FeSi₂-based thermoelectric conversion semiconductor source material powders made of p-type or n-type and a plate or powder made of a predetermined metal in at least one end part of these are put into the inside of a sintering mold, and these are sintered and bonded in one step by the electric discharge plasma sintering method. See, for example, Japanese Patent Application Laid-open No. 2010-34508.

Further, according to this method, it is supposed that a metal electrode both thermally and electrically integrated with the FeSi₂-based thermoelectric conversion semiconductor can be formed, and a connection wire made of copper or the like can be easily soldered to this electrode part.

However, in the case of the thermoelectric conversion module of International Application Publication No. 2009/001691, the thermoelectric conversion module is formed by processing an oxide thermoelectric conversion material into a sheet form and printing an insulating layer, followed by stacking and integrally firing. This necessitates a high temperature firing step, thereby raising a problem in that the energy needed for production is large and also the production process is long.

Also, in the case of the method of Japanese Patent Application Laid-open No. 08-139368, a thermal treatment at a high temperature is needed in order to obtain the FeSi₂ thermal power-generating element, thereby raising a problem in that the production process is long.

Also, according to the method of Japanese Patent Application Laid-open No. 2010-34508, the element is made by using electric discharge plasma sintering, so that the method has a characteristic feature such that a metal electrode both thermally and electrically integrated with the thermoelectric conversion semiconductor can be formed. However, this needs electric discharge plasma sintering, thereby raising a problem in that the equipment cost and the energy cost are large, and also the productivity is low.

### SUMMARY OF THE INVENTION

In view of the aforementioned circumstances, preferred embodiments of the present invention provide a thermoelectric conversion module capable of being efficiently produced and having a high productivity without the need for steps such as firing and heat treatment at a high temperature, and a method for producing such a thermoelectric conversion module.

A thermoelectric conversion module according to a preferred embodiment of the present invention is a thermoelectric conversion module having a stack structure in which a one-side element and an other-side element are alternately stacked; the one-side element and the other-side element are directly bonded in some regions of a bonding surface at which the one-side element and the other-side element are bonded; and the one-side element and the other-side element are bonded via an insulating material in other regions of the bonding surface, wherein at least one of the one-side element and the other-side element is a thermoelectric conversion element including a thermoelectric conversion material powder made of an intermetallic compound and a metal powder and being retained to have a predetermined shape by a cured resin.

Also, a thermoelectric conversion module according to a preferred embodiment of the present invention is a thermoelectric conversion module having a stack structure in which a p-type thermoelectric conversion element and an n-type thermoelectric conversion element are alternately stacked; the p-type thermoelectric conversion element and the n-type thermoelectric conversion element are directly bonded in some regions of a bonding surface at which the p-type thermoelectric conversion element and the n-type thermoelectric conversion element are bonded; and the p-type thermoelectric conversion element and the n-type thermoelectric conversion element are bonded via an insulating material in other regions of the bonding surface, wherein at least one of the p-type thermoelectric conversion element and the n-type thermoelectric conversion element is a thermoelectric conversion element including a thermoelectric conversion material powder made of an intermetallic compound and a metal powder and being retained to have a predetermined shape by a cured resin.

Also, a thermoelectric conversion module according to a preferred embodiment of the present invention is a thermoelectric conversion module having a stack structure in which a p-type thermoelectric conversion element and an electroconductive material element are alternately stacked; the p-type thermoelectric conversion element and the electroconductive material element are directly bonded in some regions of a bonding surface at which the p-type thermoelectric conversion element and the electroconductive material element are bonded; and the p-type thermoelectric conversion element and the electroconductive material element are bonded via an insulating material in other regions of the bonding surface, wherein at least one of the p-type thermoelectric conversion element is a thermoelectric conversion element including a thermoelectric conversion material powder made of an intermetallic compound and a metal powder and being retained to have a predetermined shape by a cured resin.

Also, a thermoelectric conversion module according to a preferred embodiment of the present invention is a thermoelectric conversion module having a stack structure in which an n-type thermoelectric conversion element and an electroconductive material element are alternately stacked; the n-type thermoelectric conversion element and the electroconductive material element are directly bonded in some regions of a bonding surface at which the n-type thermoelectric conversion element and the electroconductive material element are bonded; and the n-type thermoelectric conversion element and the electroconductive material element are bonded via an insulating material in other regions of the bonding surface, wherein at least one of the n-type thermoelectric conversion element is a thermoelectric conversion element including a thermoelectric conversion material powder made of an intermetallic compound and a metal powder and being retained to have a predetermined shape by a cured resin.

Also, in a thermoelectric conversion module according to a preferred embodiment of the present invention, it is preferable that the intermetallic compound constituting the thermoelectric conversion element is a silicide.

Also, it is preferable that the silicide is at least one kind selected from the group consisting of magnesium silicide, manganese silicide, and iron silicide.

Also, in a thermoelectric conversion module according to a preferred embodiment of the present invention, it is preferable that the thermoelectric conversion element including a thermoelectric conversion material powder made of an intermetallic compound and a metal powder and being retained to have a predetermined shape by a cured resin is one formed by curing a curable resin that is applied onto or allowed to penetrate into a molded article including the thermoelectric conversion material powder made of the intermetallic compound and the metal powder.

Also, a method for producing a thermoelectric conversion module according to a preferred embodiment of the present invention is a method for producing a thermoelectric conversion module including a stacked body in which a one-side element and an other-side element are alternately stacked; the one-side element and the other-side element are directly bonded in some regions of a bonding surface at which the one-side element and the other-side element are bonded; and the one-side element and the other-side element are bonded via an insulating material in other regions of the bonding surface, wherein at least one of the one-side element and the other-side element is a thermoelectric conversion element including a thermoelectric conversion material powder made of an intermetallic compound and a metal powder and being retained to have a predetermined shape by a cured resin, the method including a step of forming a precursor stacked body that is turned into the stacked body by applying the resin or allowing the resin to penetrate and curing the resin, the precursor stacked body including a precursor layer that is made of the thermoelectric conversion material made of the intermetallic compound and the metal powder so as to be turned into the one-side element and/or the other-side element layer by applying the resin or allowing the resin to penetrate and curing the resin; a step of applying a curable resin onto the precursor stacked body or allowing a curable resin to penetrate into the precursor stacked body; and a step of curing the curable resin.

Also, in a method for producing a thermoelectric conversion module according to a preferred embodiment of the present invention, it is preferable that the precursor stacked body is one formed by thermally treating a stacked structure body including a green sheet that contains the thermoelectric conversion material made of the intermetallic compound, the metal powder, and a binder so as to be turned into the precursor layer, so as to remove organic components, and thereafter pressurizing.

A thermoelectric conversion module according to a preferred embodiment of the present invention is a thermoelectric conversion module having a stack structure in which a one-side element and an other-side element are alternately stacked; the one-side element and the other-side element are directly bonded in some regions of a bonding surface of the one-side element and the other-side element; and the one-side element and the other-side element are bonded via an insulating material in other regions of the bonding surface, wherein at least one of the one-side element and the other-side element is a thermoelectric conversion element including a thermoelectric conversion material powder made of an intermetallic compound and a metal powder and being retained to have a predetermined shape by a cured resin. Such a thermoelectric conversion element is produced without the need for a sintering step, so that a thermoelectric conversion module that is excellent in mass production property is provided at a low cost.

Also, another thermoelectric conversion module according to a preferred embodiment of the present invention is a thermoelectric conversion module having a stack structure in which a p-type thermoelectric conversion element and an n-type thermoelectric conversion element are alternately stacked; the p-type thermoelectric conversion element and the n-type thermoelectric conversion element are directly bonded in some regions of a bonding surface of the p-type thermoelectric conversion element and the n-type thermoelectric conversion element; and the p-type thermoelectric conversion element and the n-type thermoelectric conversion element are bonded via an insulating material in other regions of the bonding surface, wherein at least one of the p-type thermoelectric conversion element and the n-type thermoelectric conversion element is a thermoelectric conversion element including a thermoelectric conversion material powder made of an intermetallic compound and a metal powder and being retained to have a predetermined shape by a cured resin. Such a thermoelectric conversion element is produced without the need for a sintering step, so that a thermoelectric conversion module that is excellent in mass production property is provided at a low cost.

Also, still another thermoelectric conversion module according to a preferred embodiment of the present invention is a thermoelectric conversion module having a stack structure in which a p-type thermoelectric conversion element and an electroconductive material element are alternately stacked; the p-type thermoelectric conversion element and the electroconductive material element are directly bonded in some regions of a bonding surface; and the p-type thermoelectric conversion element and the electroconductive material element are bonded via an insulating material in other regions of the bonding surface, when at least one of the p-type thermoelectric conversion element and the electroconductive material element is a thermoelectric conversion element including a thermoelectric conversion material powder made of an intermetallic compound and a metal powder and being retained to have a predetermined shape by a cured resin. The thermoelectric conversion element is produced without the need for a sintering step, so that a thermoelectric conversion module that is excellent in mass production property is provided at a low cost.

Also, still another thermoelectric conversion module according to a preferred embodiment of the present invention is a thermoelectric conversion module having a stack structure in which a n-type thermoelectric conversion element and an electroconductive material element are alternately stacked; the n-type thermoelectric conversion element and the electroconductive material element are directly bonded in some regions of a bonding surface; and the n-type thermoelectric conversion element and the electroconductive material element are bonded via an insulating material in other regions of the bonding surface, when at least one of the n-type thermoelectric conversion element and the electroconductive material element is a thermoelectric conversion element including a thermoelectric conversion material powder made of an intermetallic compound and a metal powder and being retained to have a predetermined shape by a cured resin. The thermoelectric conversion element is produced without the need for a sintering step, so that a thermoelectric conversion module that is excellent in mass production property is provided at a low cost.

Also, by using a silicide as the intermetallic compound, a thermoelectric conversion material having a high thermoelectric conversion efficiency is obtained without the need for a sintering step at a high temperature or the like, so that the various preferred embodiments of the present invention are more effective.

Also, by using, as the silicide, at least one kind selected from the group consisting of magnesium silicide, manganese silicide, and iron silicide, a thermoelectric conversion module having good characteristics and being excellent in economical property is provided.

Also, when the thermoelectric conversion element including a thermoelectric conversion material powder made of an intermetallic compound and a metal powder and being retained to have a predetermined shape by a cured resin is a thermoelectric conversion element formed by curing a curable resin that is applied onto or allowed to penetrate into a molded article including the thermoelectric conversion material powder made of the intermetallic compound and the metal powder, a thermoelectric conversion module capable of being efficiently produced without the need for a sintering step at a high temperature or the like is provided.

In producing a thermoelectric conversion module having a stacked body in which a one-side element and an other-side element are alternately stacked; the one-side element and the other-side element are directly bonded in some regions of a bonding surface; and the one-side element and the other-side element are bonded via an insulating material in other regions of the bonding surface, wherein at least one of the one-side element and the other-side element is a thermoelectric conversion element including a thermoelectric conversion material powder made of an intermetallic compound and a metal powder and being retained to have a predetermined shape by a cured resin, a thermoelectric conversion module according to a preferred embodiment of the present invention having a stack structure is efficiently produced without the need for a sintering step at a high temperature or the like by performing a step of forming a precursor stacked body including a precursor layer that is made of the thermoelectric conversion material made of the intermetallic compound and the metal powder so as to be turned into the one-side element and/or the other-side element layer by applying the resin or allowing the resin to penetrate and curing the resin, a step of applying a curable resin onto the precursor stacked body or allowing a curable resin to penetrate into the precursor stacked body, and a step of curing the curable resin.

Also, a thermoelectric conversion module according to a preferred embodiment of the present invention having a stack structure is produced more efficiently by forming the precursor stacked body through thermally treating a stacked structure body including a green sheet that includes the thermoelectric conversion material made of the intermetallic compound, the metal powder, and a binder so as to be turned into the precursor layer, so as to remove organic components, and thereafter pressurizing.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a view illustrating a construction of a thermoelectric conversion module according to Examples 1 to 3 of a preferred embodiment of the present invention.

FIG. 2 is a view illustrating a construction of a thermoelectric conversion module according to Example 4 of a preferred embodiment of the present invention and a Comparative Example.

FIG. 3 is a view illustrating a construction of a thermoelectric conversion module according to Example 5 of a preferred embodiment of the present invention.

FIG. 4 is a model view illustrating a thermoelectric conversion element obtained by adding a metal powder to a thermoelectric conversion material and being in a state in which the shape is retained by a cured resin, which is used in the thermoelectric conversion module of a preferred embodiment of the present invention.

FIG. 5 is a view showing power generation characteristics of the thermoelectric conversion module according to Example 1 of a preferred embodiment of the present invention.

FIG. 6 is a view showing power generation characteristics of the thermoelectric conversion module according to Example 2 of a preferred embodiment of the present invention.

FIG. 7 is a view showing power generation characteristics of the thermoelectric conversion module according to Example 3 of a preferred embodiment of the present invention.

FIG. 8 is a view showing power generation characteristics of the thermoelectric conversion module according to Example 4 of a preferred embodiment of the present invention.

FIG. 9 is a view showing power generation characteristics of the thermoelectric conversion module according to Example 5 of a preferred embodiment of the present invention.

FIG. 10 is a view showing power generation characteristics of the thermoelectric conversion module according to the Comparative Example.

FIG. 11 is a view illustrating a basic construction of a π-type thermoelectric conversion module and a function thereof.

### DETAILED DESCRIPTION OF THE PREFERRED EMBODIMENTS

Hereafter, preferred embodiments of the present invention will be shown to describe the characteristic features of the present invention in further more detail.

For example, referring to FIG. 11, when π-type thermoelectric conversion element (the p-n junction pair constitutes one thermoelectric conversion module) 110 including one p-type thermoelectric conversion material 101 and one n-type thermoelectric conversion material 102, where p-type thermoelectric conversion material 101 and n-type thermoelectric conversion material 102 are connected via high temperature-side connection electrode 104 on high temperature-side end surface 103a, and electrode (collecting electrode) 105 is disposed on low temperature-side end surface 103b of each of p-type thermoelectric conversion material 101 and n-type thermoelectric conversion material 102, is considered, electromotive force is generated by the Seebeck effect when a temperature difference is given between high temperature-side end surface 103a and low temperature-side end surface 103b, such that electric power is collected through electrode (collecting electrode) 105.

Here, the Seebeck coefficient of the p-type thermoelectric conversion material is positive, and the Seebeck coefficient of the n-type thermoelectric conversion material is negative, so that a large thermal electromotive force can be obtained by forming a plurality of p-n junction pairs.

However, the present invention is not limited to the case in which the thermoelectric conversion module includes a combination of a p-type thermoelectric conversion material and an n-type thermoelectric conversion material, so that a thermoelectric conversion module capable of generating a predetermined electromotive force can be constructed also by combining a p-type thermoelectric conversion material with a metal material or combining an n-type thermoelectric conversion material with a metal material.

In the meantime, when a metal oxide semiconductor-based material is used as p-type and n-type thermoelectric conversion materials as described above, the metal oxide semiconductor-based material is typically produced in such a manner that a thermoelectric conversion material produced through the steps of mixing metal compound materials (oxides, carbonates, and others) in a predetermined blending ratio, thereafter performing a heat treatment to synthesize a source material powder having a desired composition, and further sintering the resultant by a method such as pressure-sintering is cut out into a predetermined shape to form thermoelectric conversion materials (p-type thermoelectric conversion element and n-type thermoelectric conversion element) which are then electrically connected to form a π-type junction structure such as shown in FIG. 11, for example. For this reason, in order to fabricate a p-type thermoelectric conversion material (element) and an n-type thermoelectric conversion material (element), a sintering step is essential, leading to increase in the energy costs and involving complex production steps.

Also, in the case of a π-type junction structure such as shown in FIG. 11, a void gap layer for insulation is provided between p-type thermoelectric conversion material 101 and n-type thermoelectric conversion material 102, so that there is inherently a limit to enhancing the occupancy of the thermoelectric conversion materials.

In contrast, in preferred embodiments of the present invention, an intermetallic compound such as magnesium silicide or manganese silicide fabricated by a method such as the melting method, for example, is preferably used as the thermoelectric conversion materials, the thermoelectric conversion materials are obtained without the need for a step of firing at a high temperature such as in the case of using an oxide semiconductor as a thermoelectric conversion material.

Also, as described later, a thermoelectric conversion module according to a preferred embodiment of the present invention has a stack structure in which, for example, a p-type thermoelectric conversion material and an n-type thermoelectric conversion material are directly bonded in some regions of a bonding surface of the p-type thermoelectric conversion material and the n-type thermoelectric conversion material, and the p-type thermoelectric conversion material and the n-type thermoelectric conversion material are bonded via an insulating material in other regions of the bonding surface. This eliminates the need for a void gap layer for insulation, so that the occupancy of the thermoelectric conversion materials is enhanced, and the power generation efficiency per unit volume is increased.

Also, at least some of the thermoelectric conversion elements constituting the thermoelectric conversion module according to a preferred embodiment of the present invention are thermoelectric conversion elements including a thermoelectric conversion material powder and a metal powder and being retained to have a predetermined shape by a cured resin, and such thermoelectric conversion elements can be produced by curing a curable resin that is applied onto or allowed to penetrate into a molded article including the thermoelectric conversion material powder made of an intermetallic compound and the metal powder, so that a thermoelectric conversion module is efficiently produced without the need for a sintering step at a high temperature or the like.

The kind of the intermetallic compound (metal-based semiconductor thermoelectric conversion material) used in the thermoelectric conversion material of the present invention is not particularly limited. However, it is preferable to use a metal-based semiconductor thermoelectric conversion material such as a silicide-based material, a Heusler-based material, a half Heusler-based material, or a Skutterudite-based material, more preferably a silicide material such as magnesium silicide (for example, Mg₂Si), manganese silicide (for example, MnSi_{1.7}), or iron silicide (for example, FeSi₂), for example.

Also, in some of the thermoelectric conversion elements constituting the thermoelectric conversion module according to various preferred embodiments of the present invention, a thermoelectric conversion material powder made of an intermetallic compound is mixed with a metal powder which is a material having a lower resistivity than the thermoelectric conversion material.

The kind of the metal powder to be added is not particularly limited as long as the metal powder has a lower resistivity than the thermoelectric conversion material. Also, either one kind of a metal powder may be singly used or two or more kinds may be used by being mixed. Also, it is desirable to use a metal powder having a smaller particle size than the thermoelectric conversion material powder and, typically, it is preferable that the metal powder is added in a powder state.

Also, in relation to the combination of the thermoelectric conversion material and the metal powder, it is preferable to combine a metal having the same polarity as the polarity of the Seebeck coefficient of the thermoelectric conversion material in order to reduce the resistivity while restraining the decrease in the Seebeck coefficient.

In various preferred embodiments of the present invention, Ni powder can be a preferable example of a metal powder that is mixed with the n-type thermoelectric conversion material powder, and Cu powder can be a preferable example of a metal powder that is mixed with the p-type thermoelectric conversion material powder.

Here, the amount of addition of the metal powder is preferably such that the ratio of the metal powder relative to the sum of the amounts of the metal powder and the thermoelectric conversion material powder preferably is within a range from about 0.1 vol % to about 50 vol %, for example. This is due to the following reason. When the amount of addition of the metal powder is less than about 0.1 vol %, effective decrease in the resistivity is not generated. Also, when the amount of addition of the metal powder exceeds about 50 vol %, the Seebeck coefficient decreases, leading to decrease in the power generation characteristics.

Also, regarding a powder that is a starting source material of the thermoelectric conversion material powder constituting the thermoelectric conversion element including the thermoelectric conversion material powder and the metal powder and being retained to have a predetermined shape by a cured resin that is used in the thermoelectric conversion module of a preferred embodiment of the present invention, a powder obtained by grinding and mixing the source material powder with a ball mill, for example, is preferably used. The time, the particle size, and others in grinding and mixing the source material powder with a ball mill are not particularly limited; however, the time is preferably determined in consideration of homogeneous grinding and mixing.

Also, in forming a stack structure body in which the one-side element and the other-side element are directly bonded in some regions of the bonding surface and the one-side element and the other-side element are bonded via an insulating material in other regions of the bonding surface, the stacked body can be formed, for example, by using a green sheet obtained by molding a material including the thermoelectric conversion material powder and the metal powder into a sheet form. For this green sheet, a green sheet having a good homogeneity and smoothness is preferably used.

Also, in fabricating the above green sheet, the green sheet including the thermoelectric conversion material powder and the metal powder can be obtained typically by further adding a binder to a mixed material of the thermoelectric conversion material powder and the metal powder to form a slurry and thereafter molding the slurry into a sheet form by the doctor blade method.

However, the molding method is not particularly limited as long as the slurry can be formed into a sheet form with a film thickness as designed.

Also, the insulating material (layer) that insulates the portions of the regions of the bonding surface of the one-side element and the other-side element can be formed, for example, by printing an insulating material paste onto a green sheet.

The insulating material (paste) to be printed may be any as long as the insulating material can form a layer that can maintain the insularity between the one-side element and the other-side element (specifically, between the p-type thermoelectric conversion element and the n-type thermoelectric conversion element or between the p-type thermoelectric conversion element or the n-type thermoelectric conversion element and the metal layer (electroconductive material element)).

Therefore, a paste including an insulating ceramic material such as alumina or an insulating material powder such as glass as a major insulating component, for example, can be used.

Further, an organic substance having a heat resistance that can resist a temperature higher than the temperature for removing the binder (organic substance) constituting the green sheet, for example, can be used as well.

Also, with regard to the method for forming the insulating material (layer), the insulating material (layer) can be formed, for example, by the screen printing method. However, the forming method thereof is not particularly limited, so that other methods such as the gravure printing method can be used as well.

Also, the thermoelectric conversion module according to various preferred embodiments of the present invention can be formed simply by using pressure-molding alone without using the heating and pressure-sintering method by which heating and sintering are carried out while pressurizing.

In producing the thermoelectric conversion module according to various preferred embodiments of the present invention, a molded article before application or penetration of a curable resin can be obtained, for example, by stacking green sheets including a thermoelectric conversion material on which an insulating material (layer) is formed in a predetermined region by printing an insulating material paste, thereafter performing press-bonding, removing organic components (binder) in the green sheet, and thereafter pressurizing under hydrostatic pressure of a high pressure.

Subsequently, a curable resin is applied onto or allowed to penetrate into the surface of the molded article (stacked body) that has been subjected to pressure-molding.

The resin that is allowed to penetrate may be, for example, a thermosetting one such as an epoxy resin, a photosetting resin, a resin of a type that is cured by a curing promoter or a catalyst, or the like.

Also, the application state or penetration state of the curable resin may be any as long as at least the molded article can sustain the shape thereof, so that the distance by which the resin extends from the surface to the inside of the molded article is not particularly limited.

Also, a method of allowing the resin to penetrate may be a technique such as the pressure impregnation method or the vacuum impregnation method.

The thickness of each layer constituting the thermoelectric conversion module, the number of pairs of p-type thermoelectric conversion elements and n-type thermoelectric conversion elements, and the like are suitably selected in consideration of the targeted electromotive force, electric current, resistance of the load to be used, and the like.

As described above, the thermoelectric conversion module according to various preferred embodiments of the present invention does not need heating and pressure-sintering, which enables economical mass production without consumption of a large energy in the production steps.

Further, by mixing a low-resistance material (metal powder) into the thermoelectric conversion material powder, the resistivity of the thermoelectric conversion element can be lowered, thus improving the power generation performance of the element.

Also, since a direct connection between the thermoelectric conversion elements is established instead of assembling the modules after individual thermoelectric conversion elements are fabricated as in the case of forming the modules using a π-type thermoelectric conversion element, the contact resistance is significantly reduced.

Furthermore, the p-type thermoelectric conversion material, the n-type thermoelectric conversion material, and the insulating material can be integrated by a pressurizing process. This eliminates the need for a void gap between the elements that was needed for insulation between the thermoelectric conversion materials, so that a thermoelectric conversion module having a large mechanical strength is provided.

Also, though a stacked body simply subjected to pressure-molding has a weak mechanical strength at the end portions, high strength can be achieved by curing the resin after application or penetration of the curable resin, thus enhancing the reliability.

### EXAMPLES

Hereafter, non-limiting examples of various preferred embodiments of the present invention will be shown to describe various preferred embodiments of the present invention further in more detail.

### [1] Preparation of Materials for Thermoelectric Conversion Module

(1) Materials for Fabrication of Thermoelectric Conversion Module of Example 1

As a p-type thermoelectric conversion material (p-type semiconductor thermoelectric conversion material), MnSi_{1.7} fabricated by the melting method was prepared. As an n-type thermoelectric conversion material (n-type semiconductor thermoelectric conversion material), Mg₂Si fabricated by the melting method was prepared.

Further, the p-type thermoelectric conversion material (MnSi_{1.7}) and n-type thermoelectric conversion material (Mg₂Si) were ground with a mortar and classified to have a particle size of about 75 μm or less.

Subsequently, a Cu powder having a central particle size of about 0.75 μm was added in an amount of about 5 vol % into this classified p-type thermoelectric conversion material (MnSi_{1.7}).

Also, a Ni powder having a central particle size of about 0.9 μm was added in an amount of about 10 vol % into the classified n-type thermoelectric conversion material powder (Mg₂Si).

In this manner, preparation of the materials for a thermoelectric conversion module provided with a p-type thermoelectric conversion element (one-side element) made of the p-type thermoelectric conversion material to which the metal powder (Cu powder) had been added and an n-type thermoelectric conversion element (other-side element) made of the n-type thermoelectric conversion material to which the metal powder (Ni powder) had been added was carried out.

(2) Materials for Fabrication of Thermoelectric Conversion Module of Example 2

As a p-type thermoelectric conversion material (p-type semiconductor thermoelectric conversion material), MnSi_{1.7} was prepared. As an n-type thermoelectric conversion material (n-type semiconductor thermoelectric conversion material), Mg₂Si was prepared.

Further, these p-type thermoelectric conversion material (MnSi_{1.7}) and n-type thermoelectric conversion material (Mg₂Si) were ground with a mortar and classified to have a particle size of about 75 μm or less.

Further, a metal powder was not particularly added into the classified p-type thermoelectric conversion material (MnSi_{1.7}), whereby a material for forming a p-type thermoelectric conversion element (one-side element) was prepared.

On the other hand, a Ni powder having a central particle size of about 0.9 μm was added in an amount of about 10 vol % as a metal powder into the classified n-type thermoelectric conversion material powder (Mg₂Si), whereby a material for forming an n-type thermoelectric conversion element (other-side element) was prepared.

(3) Materials for Fabrication of Thermoelectric Conversion Module of Example 3

As a p-type thermoelectric conversion material (p-type semiconductor thermoelectric conversion material), MnSi_{1.7} was prepared. As an n-type thermoelectric conversion material (n-type semiconductor thermoelectric conversion material), Mg₂Si was prepared.

Further, these p-type thermoelectric conversion material (MnSi_{1.7}) and n-type thermoelectric conversion material (Mg₂Si) were ground with a mortar and classified to have a particle size of about 75 μm or less.

Subsequently, a Cu powder having a central particle size of about 0.75 μm was added in an amount of about 5 vol % into this classified p-type thermoelectric conversion material (MnSi_{1.7}).

Meanwhile, a metal powder was not particularly added into the classified n-type thermoelectric conversion material powder (Mg₂Si), whereby a material for forming an n-type thermoelectric conversion element (other-side element) was prepared.

(4) Materials for Fabrication of Thermoelectric Conversion Module of Example 4

As an n-type semiconductor thermoelectric conversion material, Mg₂Si was prepared, and this was ground with a mortar and classified to have a particle size of about 75 μm or less.

Subsequently, a Ni powder having a central particle size of about 0.9 μm was added in an amount of about 10 vol % into this classified n-type thermoelectric conversion material powder.

Also, a Cu powder having a central particle size of about 0.75 μm was prepared as an electroconductive material that would be turned into the one-side element in the case of using the n-type thermoelectric conversion element made of the above-described n-type semiconductor thermoelectric conversion material as the other-side element.

(5) Materials for Fabrication of Thermoelectric Conversion Module of Example 5

As a p-type semiconductor thermoelectric conversion material, MnSi_{1.7} was prepared, and this was ground with a mortar and classified to have a particle size of about 75 μm or less.

Subsequently, a Cu powder having a central particle size of about 0.75 μm was added in an amount of about 5 vol % into this classified MnSi_{1.7}.

Also, a Ni powder having a central particle size of about 0.9 μm was prepared as an electroconductive material that would be turned into the other-side element in the case of using the p-type thermoelectric conversion element made of the above-described p-type semiconductor thermoelectric conversion material as the one-side element.

(6) Materials for Fabrication of Thermoelectric Conversion Module of Comparative Example

As an n-type semiconductor thermoelectric conversion material, Mg₂Si was prepared, and this was ground with a mortar and classified to have a particle size of about 75 μm or less.

Further, a Cu powder having a central particle size of about 0.75 μm was prepared as an electroconductive material that would be turned into the one-side element in the case of using the n-type thermoelectric conversion element made of the above-described n-type semiconductor thermoelectric conversion material (material into which a metal powder had not been added) as the other-side element.

### [2] Fabrication of Stacked Body

Into the p-type thermoelectric conversion material, the n-type thermoelectric conversion material, and the electroconductive material (metal powder) prepared for fabrication of the thermoelectric conversion modules of Examples 1 to 5 and the thermoelectric conversion module of the Comparative Example described in the column for preparation of the materials for the thermoelectric conversion modules of the above [1], toluene, ethanol, and a binder were added and mixed for four hours. The obtained slurry was molded into a sheet form by the doctor blade method so as to fabricate green sheets, that is, a p-type thermoelectric conversion material sheet, an n-type thermoelectric conversion material sheet, and an electroconductive material sheet.

Here, with respect to the p-type thermoelectric conversion material sheet and the n-type thermoelectric conversion material sheet for the thermoelectric conversion modules of Examples 1 to 3 provided with the requirements of various preferred embodiments of the present invention, the thicknesses thereof preferably were each set to be about 60 μm, for example.

Meanwhile, with respect to the n-type thermoelectric conversion material sheet and the electroconductive material sheet for the thermoelectric conversion module of Example 4, the thickness of the n-type thermoelectric conversion material sheet was set to be about 60 μm, and the thickness of the electroconductive material sheet was set to be about 30 μm.

Also, with respect to the p-type thermoelectric conversion material sheet and the electroconductive material sheet for the thermoelectric conversion module of Example 5, the thickness of the p-type thermoelectric conversion material sheet was set to be about 60 μm, and the thickness of the electroconductive material sheet was set to be about 30 μm.

Further, with respect to the n-type thermoelectric conversion material sheet and the electroconductive material sheet for the thermoelectric conversion module of the Comparative Example, the thickness of the n-type thermoelectric conversion material sheet was set to be about 60 μm, and the thickness of the electroconductive material sheet was set to be about 30 μm.

As an insulating material, Al₂O₃ powder, varnish, and a solvent were mixed and kneaded with a roll apparatus to fabricate an insulating material paste.

Subsequently, the above-described insulating paste was printed onto the fabricated p-type and n-type thermoelectric conversion material sheets and electroconductive material sheet so that the thickness thereof would be each about 10 μm.

Thereafter, in the case of Examples 1 to 3 described above, sheets were stacked in the order of a p-type thermoelectric conversion material sheet on which the insulating material had not been printed, a p-type thermoelectric conversion material sheet on which the insulating material had been printed, an n-type thermoelectric conversion material sheet on which the insulating material had not been printed, and an n-type thermoelectric conversion material sheet on which the insulating material had been printed. As the last layer, two layers of n-type thermoelectric conversion material sheets on which the insulating material had not been printed were superposed.

Meanwhile, in the case of Example 4, sheets were stacked in the order of an electroconductive material sheet on which the insulating material had been printed, an n-type thermoelectric conversion material sheet on which the insulating material had not been printed, an n-type thermoelectric conversion material sheet on which the insulating material had been printed, and an electroconductive material sheet on which the insulating material had been printed. As the last layer, an electroconductive material sheet on which the insulating material had not been printed was stacked.

In the case of Example 5, sheets were stacked in the order of an electroconductive material sheet on which the insulating material had been printed, a p-type thermoelectric conversion material sheet on which the insulating material had not been printed, a p-type thermoelectric conversion material sheet on which the insulating material had been printed, and an electroconductive material sheet on which the insulating material had been printed. As the last layer, an electroconductive material sheet on which the insulating material had not been printed was stacked.

Also, in the Comparative Example, sheets were stacked in the order of an electroconductive material sheet on which the insulating material had been printed, an n-type thermoelectric conversion material sheet on which the insulating material had not been printed, an n-type thermoelectric conversion material sheet on which the insulating material had been printed, and an electroconductive material sheet on which the insulating material had been printed. As the last layer, an electroconductive material sheet on which the insulating material had not been printed was stacked.

Here, in all of Examples 1 to 5 and the Comparative Example, 20 pairs of respective material layers were stacked. After stacking, the resultant was inserted into a mold having a predetermined size, followed by pressurizing at a hydrostatic pressure of about 90 MPa to obtain a stacked block body.

This stacked block body was cut to have a predetermined size by using a dicing saw, so as to obtain a green stacked body.

Thereafter, this green stacked body was thermally treated at about 270° C. in ambient air to perform degreasing, so as to remove (degrease) organic substances that had constituted the green sheet.

Subsequently, with respect to the green stacked body after degreasing, the block was pressurized at about 1 GPa with a hydrostatic pressing machine, so as to obtain a molded article (that is, a stacked integrated-type thermoelectric conversion module molded article) before application or penetration of a curable resin.

Then, an epoxy resin was applied onto this molded article, and vacuum impregnation was carried out to allow the resin to penetrate into a void gap from the surface of the molded article.

Then, this resin-impregnated molded article was left to stand at room temperature for 24 hours to solidify the resin.

Thereafter, the two side surfaces that would become electrode collecting portions were exposed by polishing, so as to obtain a thermoelectric element according to a preferred embodiment of the present invention.

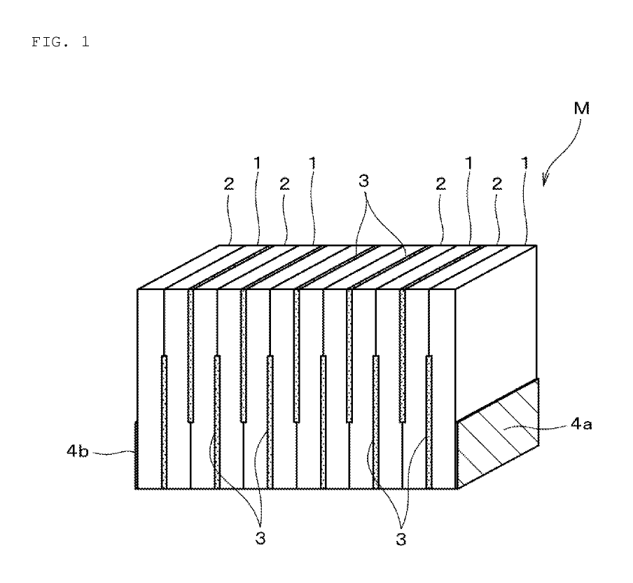

Here, in the thermoelectric conversion modules M of Examples 1 to 3, electrodes 4a, 4b (See FIG. 1) for electric power collection were formed on the two polished side surfaces.

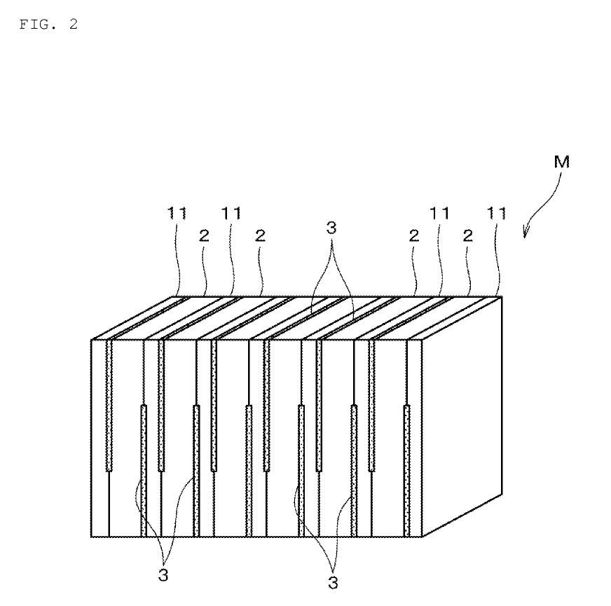

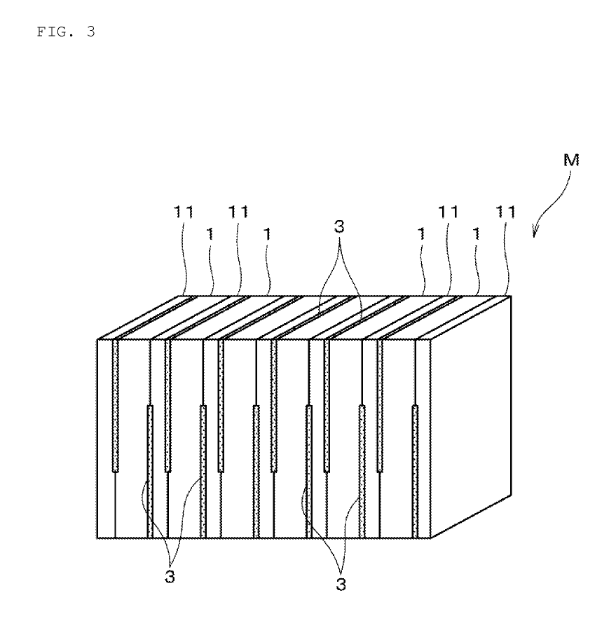

However, in Examples 4, 5 and the Comparative Example, electroconductive material elements 11 (See FIGS. 2 and 3) on the two end sides of the stacked body serve also as electrodes for collection, so that an electrode is not particularly formed.

FIG. 1 is a view illustrating a construction of a thermoelectric conversion module M of Examples 1 to 3 described above having a structure in which p-type thermoelectric conversion element 1 and n-type thermoelectric conversion element 2 are directly bonded in some regions of a bonding surface, and the p-type thermoelectric conversion element 1 and n-type thermoelectric conversion element 2 are stacked via insulating material 3 in other regions of the bonding surface.

FIG. 2 is a view illustrating a construction of a thermoelectric conversion module M of Example 4 described above having a structure in which electroconductive material element 11 and n-type thermoelectric conversion element 2 are directly bonded in some regions of a bonding surface, and the electroconductive material element 11 and n-type thermoelectric conversion element 2 are stacked via insulating material 3 in other regions of the bonding surface.

Here, the thermoelectric conversion module M of the Comparative Example has a structure such as shown in FIG. 2 except that a metal powder is not added in n-type thermoelectric conversion element 2.

FIG. 3 is a view illustrating a construction of a thermoelectric conversion module M of Example 5 described above having a structure in which p-type thermoelectric conversion element 1 and electroconductive material element 11 are directly bonded in some regions of a bonding surface, and the p-type thermoelectric conversion element 1 and electroconductive material element 11 are stacked via insulating material 3 in other regions of the bonding surface.

FIG. 4 is a model view illustrating a structure of a thermoelectric conversion element (p-type thermoelectric conversion element 1 or n-type thermoelectric conversion element 2) including thermoelectric conversion material powder 21 made of an intermetallic compound and metal powder 22 and in a state of being retained to have a predetermined shape by resin 23, which constitutes the thermoelectric conversion module of the Examples of preferred embodiments of the present invention.

Further, by providing a temperature difference of about 80° C. between the upper surface and the lower surface of the thermoelectric conversion modules of Examples 1 to 5 and the Comparative Example described above, an output voltage under no load was examined, and also the maximum output was examined by adjusting an external load so that the output might attain its maximum.

The result thereof is shown in Table 1.

TABLE 1

| | Voltage (V) | Maximum | | Electric |
|---|---|---|---|---|
| | under no | output | Voltage | current |
| | load | (mW) | (V) | (mA) |
| Example 1 | 0.29 | 1.00 | 0.14 | 7.25 |
| Example 2 | 0.31 | 0.76 | 0.15 | 5.03 |
| Example 3 | 0.33 | 0.48 | 0.16 | 2.95 |
| Example 4 | 0.17 | 0.37 | 0.08 | 4.39 |
| Example 5 | 0.15 | 0.49 | 0.08 | 6.43 |
| Comparative | 0.21 | 0.20 | 0.10 | 1.89 |
| Example | | | | |

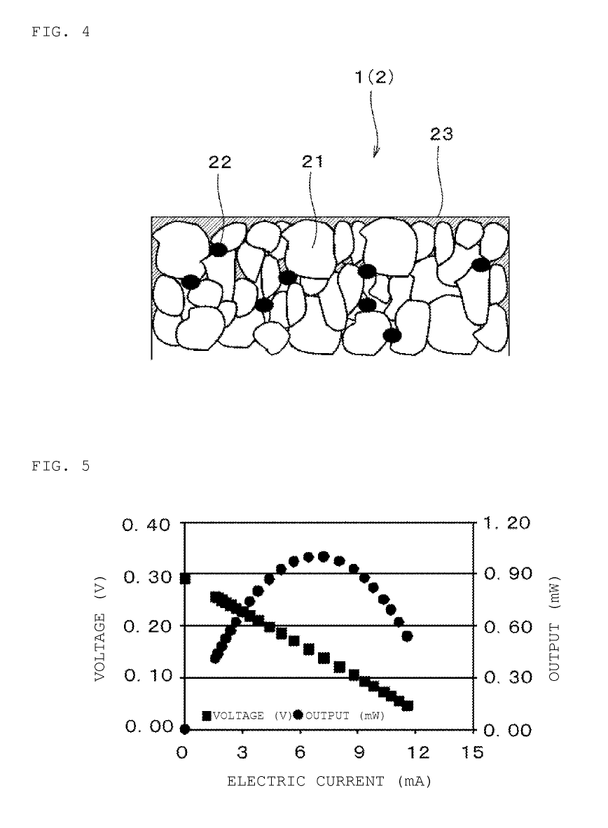

The power generation characteristics of the thermoelectric conversion module of Example 1 are shown in FIG. 5.

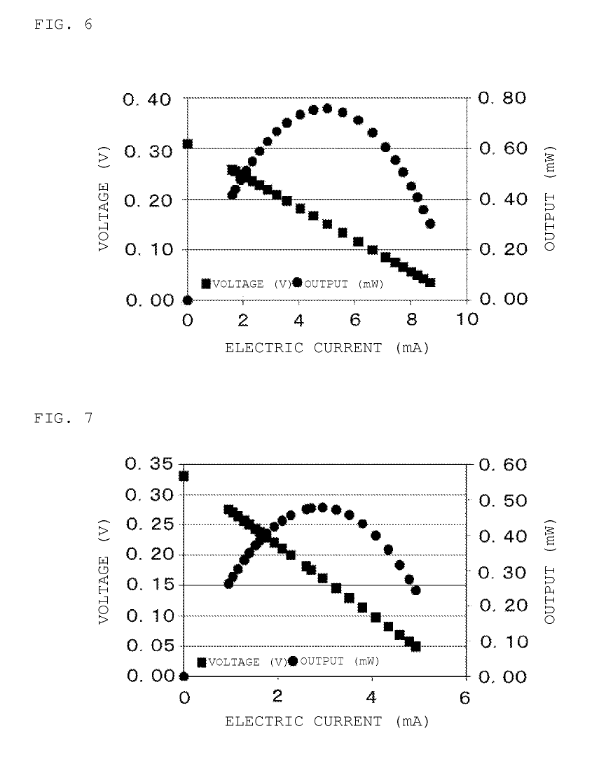

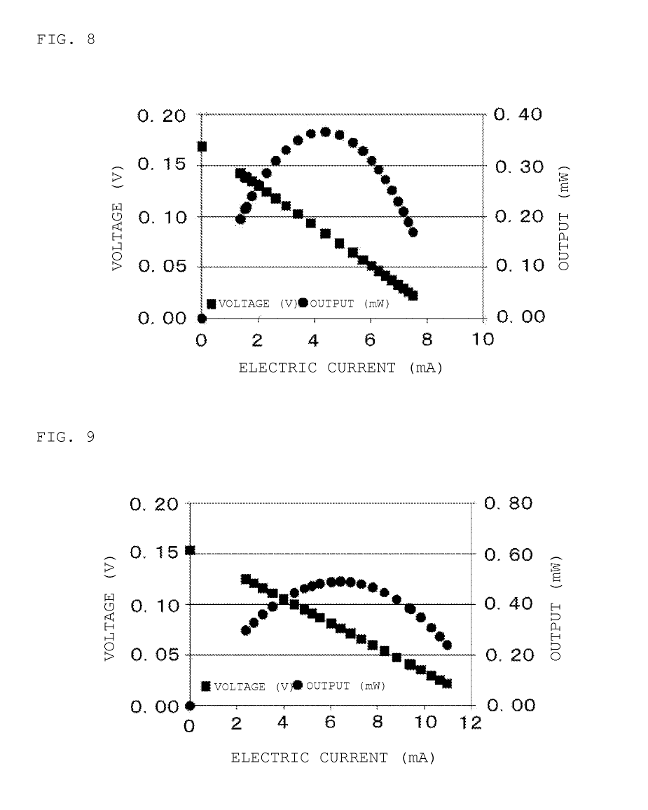

Also, the power generation characteristics of the thermoelectric conversion modules of Examples 2 and 3 are shown in FIGS. 6 and 7.

Also, the power generation characteristics of the thermoelectric conversion module of Example 4 are shown in FIG. 8.

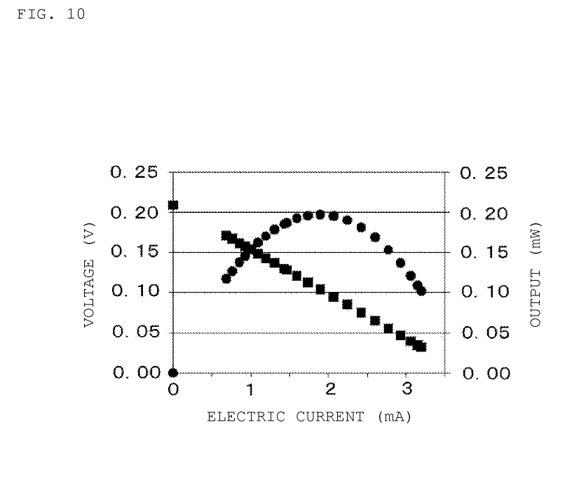

Further, the power generation characteristics of the thermoelectric conversion module of Example 5 are shown in FIG. 9.

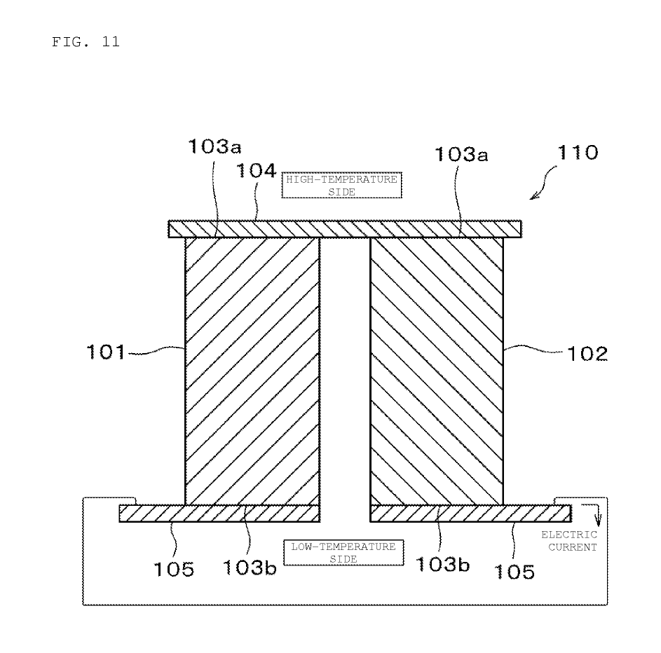

Also, the power generation characteristics of the thermoelectric conversion module of the Comparative Example are shown in FIG. 10.

Referring to Table 1 and FIG. 10, in the module of the Comparative Example in which a metal powder had not been added into the thermoelectric conversion material, the voltage under no load was about 0.21 V, and the maximum output was about 0.20 mW.

In contrast, referring to Table 1 and FIG. 5, in Example 1 in which a metal powder had been added into both of the p-type and n-type thermoelectric conversion materials, it was confirmed that the voltage under no load was about 0.29 V, and the maximum output was about 1.00 mW.

Also, referring to Table 1 and FIG. 6, in Example 2 in which a metal powder had not been added into the p-type thermoelectric conversion material and a metal powder had been added into the n-type thermoelectric conversion material, it was confirmed that the voltage under no load was about 0.31 V, and the maximum output was about 0.76 mW, thus showing an improvement in the power generation characteristics.

Further, referring to Table 1 and FIG. 7, in Example 3 in which a metal powder had not been added into the n-type thermoelectric conversion material and a metal powder had been added into the p-type thermoelectric conversion material, it was confirmed that the voltage under no load was about 0.33 V, and the maximum output was about 0.48 mW, thus showing an improvement in the power generation characteristics.

Also, referring to Table 1 and FIG. 8, in Example 4 in which an n-type thermoelectric conversion element and an electroconductive material element were combined and a metal powder had been added into the n-type thermoelectric conversion material, it was confirmed that the voltage under no load was about 0.17 V, and the maximum output was about 0.37 mW, thus showing an improvement in the power generation characteristics.

Also, referring to Table 1 and FIG. 9, in Example 5 in which a p-type thermoelectric conversion element and an electroconductive material element were combined and a metal powder had been added into the p-type thermoelectric conversion material, it was confirmed that the voltage under no load was about 0.15 V, and the maximum output was about 0.49 mW, thus showing an improvement in the power generation characteristics.

In this manner, as compared with the case of using a thermoelectric conversion material powder alone, it has been confirmed that, by adding a metal powder such as Ni or Cu, the resistivity of the thermoelectric conversion material layer is reduced, thus showing an improvement in the power generation characteristics.

Here, with respect to the combination of the thermoelectric conversion material and the metal powder, it is preferable to combine a metal having the same polarity as the polarity of the Seebeck coefficient of the thermoelectric conversion material in view of reducing the resistivity while restraining decrease in the Seebeck coefficient.

Also, because the thermoelectric conversion module according to preferred embodiments of the present invention does not need a high temperature thermal treatment in the production steps, the energy cost needed in production is reduced, and also the time needed for the production steps is reduced.

Also, in the above-described Examples, MnSi_{1.7} fabricated by the melting method is preferably used as the p-type thermoelectric conversion material, and Mg₂Si fabricated similarly by the melting method is preferably used as the n-type thermoelectric conversion material, for example. However, in various preferred embodiments of the present invention, iron silicide or the like can be used as the intermetallic compound besides magnesium silicide or manganese silicide.

Also, in the above-described Examples, a Ni powder preferably is used as the metal powder that is used in combination with the n-type thermoelectric conversion material powder, and a Cu powder preferably is used as the metal powder that is used in combination with the p-type thermoelectric conversion material powder. However, various metal powders having a lower resistivity than that of the intermetallic compound can be used as the metal powder. Here, in this case, it is preferable that the polarity of the Seebeck coefficient of the intermetallic compound constituting the thermoelectric conversion material is the same as the polarity of the Seebeck coefficient of the metal constituting the metal powder, as described above.

Here, the present invention is not limited to the above-described Examples in further other respects as well, so that various applications and modifications can be added within the scope of the present invention with respect to the number of junction pairs of the p-type thermoelectric conversion element and the n-type thermoelectric conversion element, the specific connection modes of the p-type thermoelectric conversion element and the n-type thermoelectric conversion element, and the like in the thermoelectric conversion module.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1. (canceled)

2. A thermoelectric conversion module comprising:
a stacked body including a one-side element and an other-side element that are alternately stacked; wherein
the one-side element and the other-side element are directly bonded in some regions of a bonding surface at which the one-side element and the other-side element are bonded;
the one-side element and the other-side element are bonded via an insulating material in other regions of the bonding surface; and
at least one of the one-side element and the other-side element is a thermoelectric conversion element including a thermoelectric conversion material powder made of an intermetallic compound and a metal powder and being retained to have a predetermined shape by a cured resin.

3. The thermoelectric conversion module according to claim 2, wherein the intermetallic compound constituting the thermoelectric conversion element is a silicide.

4. The thermoelectric conversion module according to claim 3, wherein the silicide is at least one kind selected from the group consisting of magnesium silicide, manganese silicide, and iron silicide.

5. The thermoelectric conversion module according to claim 2, wherein the thermoelectric conversion element including a thermoelectric conversion material powder made of an intermetallic compound and a metal powder and being retained to have a predetermined shape by a cured resin is made of a cured resin that is applied onto or penetrated into a molded article including the thermoelectric conversion material powder made of the intermetallic compound and the metal powder.

6. A thermoelectric conversion module comprising:
a stacked body including a p-type thermoelectric conversion element and an n-type thermoelectric conversion element that are alternately stacked; wherein
the p-type thermoelectric conversion element and the n-type thermoelectric conversion element are directly bonded in some regions of a bonding surface at which the p-type thermoelectric conversion element and the n-type thermoelectric conversion element are bonded;
the p-type thermoelectric conversion element and the n-type thermoelectric conversion element are bonded via an insulating material in other regions of the bonding surface; and
at least one of the p-type thermoelectric conversion element and the n-type thermoelectric conversion element is a thermoelectric conversion element including a thermoelectric conversion material powder made of an intermetallic compound and a metal powder and being retained to have a predetermined shape by a cured resin.

7. The thermoelectric conversion module according to claim 6, wherein the intermetallic compound constituting the thermoelectric conversion element is a silicide.

8. The thermoelectric conversion module according to claim 7, wherein the silicide is at least one kind selected from the group consisting of magnesium silicide, manganese silicide, and iron silicide.

9. The thermoelectric conversion module according to claim 6, wherein the thermoelectric conversion element including a thermoelectric conversion material powder made of an intermetallic compound and a metal powder and being retained to have a predetermined shape by a cured resin is made of a cured resin that is applied onto or penetrated into a molded article including the thermoelectric conversion material powder made of the intermetallic compound and the metal powder.

10. A thermoelectric conversion module comprising:
a stacked body in which a p-type thermoelectric conversion element and an electroconductive material element are alternately stacked; wherein
the p-type thermoelectric conversion element and the electroconductive material element are directly bonded in some regions of a bonding surface at which the p-type thermoelectric conversion element and the electroconductive material element are bonded;
the p-type thermoelectric conversion element and the electroconductive material element are bonded via an insulating material in other regions of the bonding surface; and
at least one of the p-type thermoelectric conversion element and the electroconductive material element is a thermoelectric conversion element including a thermoelectric conversion material powder made of an intermetallic compound and a metal powder and being retained to have a predetermined shape by a cured resin.

11. The thermoelectric conversion module according to claim 10, wherein the intermetallic compound constituting the thermoelectric conversion element is a silicide.

12. The thermoelectric conversion module according to claim 11, wherein the silicide is at least one kind selected from the group consisting of magnesium silicide, manganese silicide, and iron silicide.

13. The thermoelectric conversion module according to claim 10, wherein the thermoelectric conversion element including a thermoelectric conversion material powder made of an intermetallic compound and a metal powder and being retained to have a predetermined shape by a cured resin is made of a cured resin that is applied onto or penetrated into a molded article including the thermoelectric conversion material powder made of the intermetallic compound and the metal powder.

14. A thermoelectric conversion module comprising:
a stacked body including an n-type thermoelectric conversion element and an electroconductive material element that are alternately stacked; wherein
the n-type thermoelectric conversion element and the electroconductive material element are directly bonded in some regions of a bonding surface at which the n-type thermoelectric conversion element and the electroconductive material element are bonded;
the n-type thermoelectric conversion element and the electroconductive material element are bonded via an insulating material in other regions of the bonding surface; and
at least one of the n-type thermoelectric conversion element and the electroconductive material element is a thermoelectric conversion element including a thermoelectric conversion material powder made of an intermetallic compound and a metal powder and being retained to have a predetermined shape by a cured resin.

15. The thermoelectric conversion module according to claim 14, wherein the intermetallic compound constituting the thermoelectric conversion element is a silicide.

16. The thermoelectric conversion module according to claim 15, wherein the silicide is at least one kind selected from the group consisting of magnesium silicide, manganese silicide, and iron silicide.

17. The thermoelectric conversion module according to claim 14, wherein the thermoelectric conversion element including a thermoelectric conversion material powder made of an intermetallic compound and a metal powder and being retained to have a predetermined shape by a cured resin is made of a cured resin that is applied onto or penetrated into a molded article including the thermoelectric conversion material powder made of the intermetallic compound and the metal powder.

18. A method for producing a thermoelectric conversion module comprising a stacked body including a one-side element and an other-side element that are alternately stacked, the one-side element and an other-side element are directly bonded in some regions of a bonding surface at which the one-side element and the other-side element are bonded, and the one-side element and an other-side element are bonded via an insulating material in other regions of the bonding surface, wherein at least one of the one-side element and the other-side element is a thermoelectric conversion element including a thermoelectric conversion material powder made of an intermetallic compound and a metal powder and being retained to have a predetermined shape by a cured resin, the method comprising:
a step of forming a precursor stacked body that is turned into the stacked body by applying the resin or allowing the resin to penetrate and curing the resin, the precursor stacked body including a precursor layer that is made of the thermoelectric conversion material made of the intermetallic compound and the metal powder so as to be turned into the one-side element and/or the other-side element layer by applying the resin or allowing the resin to penetrate and curing the resin;
a step of applying a curable resin onto the precursor stacked body or allowing a curable resin to penetrate into the precursor stacked body; and
a step of curing the curable resin.

19. The method for producing a thermoelectric conversion module according to claim 18, wherein the precursor stacked body is formed by thermally treating a stacked structure body including a green sheet that includes the thermoelectric conversion material made of the intermetallic compound, the metal powder, and a binder so as to be turned into the precursor layer, so as to remove organic components, and thereafter pressurizing.

20. The method for producing a thermoelectric conversion module according to claim 18, wherein the one-side element is a p-type thermoelectric conversion element and the other-side element is an n-type thermoelectric conversion element.

21. The method for producing a thermoelectric conversion module according to claim 18, wherein one of the one-side element and the other-side element is one of a p-type thermoelectric conversion element and a n-type thermoelectric conversion element, and the other of the one-side element and the other-side element is an electroconductive material element.
